(19) United States
(12) Patent Application Publication
(10) Pub. No.: US 2025/0330142 A1
(43) Pub. Date: Oct. 23, 2025

(54) Resonator Device

(71) Applicant: SEIKO EPSON CORPORATION, Tokyo (JP)

(72) Inventor: Yoshihiko YOKOYAMA, Chino (JP)

(21) Appl. No.: 19/185,689

(22) Filed: Apr. 22, 2025

(30) Foreign Application Priority Data
Apr. 23, 2024 (JP) 2024-069546

(51) Int. Cl. H03H 9/10; H03H 3/02; H03H 9/05; H03H 9/19

(52) U.S. Cl. CPC H03H 9/1021; H03H 3/02; H03H 9/0557; H03H 9/19; H03H 2003/022

(57) ABSTRACT

A resonator device includes a semiconductor substrate having a through hole, a resonator element provided to the semiconductor substrate, a lid which is bonded to an outer circumferential portion of a first surface of the semiconductor substrate and is configured to house the resonator element between the lid and the first surface, an oscillation circuit which is disposed on the first surface and is configured to oscillate the resonator element, a terminal disposed on a second surface of the semiconductor substrate, and a through electrode which is provided to the through hole and is configured to electrically couple the terminal and the oscillation circuit, wherein the through electrode is disposed closer to the outer circumferential portion than to a center of the first surface in a plan view of the semiconductor substrate.

The present application is based on, and claims priority from JP Application Serial Number 2024-069546, filed Apr. 23, 2024, the disclosure of which is hereby incorporated by reference herein in its entirety.

### BACKGROUND

### 1. Technical Field

The present disclosure relates to a resonator device.

### 2. Related Art

JP-A-2021-72464 discloses a resonator device including a semiconductor substrate having a first surface and a second surface in an obverse-reverse relationship, a resonator element provided to the semiconductor substrate, an oscillation circuit provided on the first surface of the semiconductor substrate and configured to oscillate the resonator element, a terminal disposed on the second surface of the semiconductor substrate, a through electrode which penetrates from the second surface of the semiconductor substrate to the first surface thereof and is configured to electrically couple the terminal and the oscillation circuit, and a lid bonded to an outer circumferential portion of the semiconductor substrate so as to house the resonator element.

JP-A-2021-72464 is an example of the related art.

Since such a resonator device includes the through electrode, there is a concern over a decrease in strength in the semiconductor substrate provided with the through electrode.

### SUMMARY

A resonator device according to an aspect of the present application includes a semiconductor substrate which has a first surface and a second surface in an obverse- reverse relationship and has a through hole penetrating from the first surface to the second surface, a resonator element provided to the semiconductor substrate, a lid which is bonded to an outer circumferential portion of the first surface of the semiconductor substrate and is configured to house the resonator element between the lid and the first surface of the semiconductor substrate, an oscillation circuit which is disposed on the first surface of the semiconductor substrate and is configured to oscillate the resonator element, a terminal disposed on the second surface of the semiconductor substrate, and a through electrode which is provided to the through hole of the semiconductor substrate and is configured to electrically couple the terminal and the oscillation circuit, wherein the through electrode is disposed closer to the outer circumferential portion than to a center of the first surface in a plan view of the semiconductor substrate.

A resonator device according to an aspect of the present application includes a semiconductor substrate which has a first surface and a second surface in an obverse-reverse relationship and has a first through hole, a second through hole, a third through hole, and a fourth through hole all penetrating from the first surface to the second surface, a resonator element provided to the semiconductor substrate, a lid which is bonded to an outer circumferential portion of the first surface of the semiconductor substrate, and is configured to house the resonator element between the lid and the first surface of the semiconductor substrate, an oscillation circuit which is disposed on the first surface of the semiconductor substrate and is configured to oscillate the resonator element, a first terminal, a second terminal, a third terminal, and a fourth terminal arranged on the second surface of the semiconductor substrate, a first through electrode which is provided to the first through hole of the semiconductor substrate and is configured to electrically couple the first terminal and the oscillation circuit, a second through electrode which is provided to the second through hole of the semiconductor substrate and is configured to electrically couple the second terminal and the oscillation circuit, a third through electrode which is provided to the third through hole of the semiconductor and substrate is configured to electrically couple the third terminal and the oscillation circuit, and a fourth through electrode which is provided to the fourth through hole of the semiconductor substrate and is configured to electrically couple the fourth terminal and the oscillation circuit, wherein the first through electrode, the second through electrode, the third through electrode, and the fourth through electrode are disposed closer to the outer circumferential portion than to a center of the first surface in a plan view of the semiconductor substrate.

### BRIEF DESCRIPTION OF THE DRAWINGS

FIG. 1 is a perspective view of a resonator device according to Embodiment 1.

FIG. 2 is a perspective view of the resonator device shown in FIG. 1 viewed from a reverse side.

FIG. 3A is a cross-sectional view of the resonator device along the line A-A in FIGS. 1 and 4.

FIG. 3B is an enlarged view of the region C in FIG. 3A.

FIG. 4 is a plan view of a semiconductor substrate.

FIG. 5 is a plan view of the semiconductor substrate and a resonator.

FIG. 6 is a cross-sectional view of the resonator device along the line B-B in FIG. 1.

FIG. 7 is a block diagram showing a configuration example of a semiconductor circuit.

FIG. 8 is a flowchart representing manufacturing steps of the resonator device.

FIG. 9 is a flowchart representing details of a through electrode forming step S4 in FIG. 8.

FIG. 10 is a cross-sectional view illustrating an aspect in a manufacturing process.

FIG. 11 is a cross-sectional view illustrating an aspect in the manufacturing process.

FIG. 12 is a cross-sectional view illustrating an aspect in the manufacturing process.

FIG. 13 is a cross-sectional view illustrating an aspect in the manufacturing process.

FIG. 14 is a cross-sectional view illustrating an aspect in the manufacturing process.

FIG. 15 is a cross-sectional view illustrating an aspect in the manufacturing process.

FIG. 16 is a cross-sectional view illustrating an aspect in the manufacturing process.

FIG. 17 is a cross-sectional view illustrating an aspect in the manufacturing process.

FIG. 18 is a cross-sectional view illustrating an aspect in the manufacturing process.

FIG. 19 is a cross-sectional view illustrating an aspect in the manufacturing process.

FIG. 20 is a cross-sectional view illustrating an aspect in the manufacturing process.

FIG. 21 is a cross-sectional view illustrating an aspect in the manufacturing process.

### DESCRIPTION OF EMBODIMENTS

In an embodiment of the present disclosure, in some cases, elements illustrated in the drawings are illustrated with respective dimensional scales made different from each other in order to make the elements eye-friendly.

In the drawings, in some cases, three axes of an X axis, a Y axis, and a Z axis orthogonal to one another are illustrated. In the following description, in some cases, a tip side of an arrow of three axes is described as a “positive side”, and a base end side of the arrow is described as a “negative side”. In some cases, a direction parallel to the X axis is described as an “x-axis direction”, a direction parallel to the Y axis is described as a “Y-axis direction”, and a direction parallel to the Z axis is described as a “Z-axis direction”. In some cases, viewing in the Z-axis direction is described as “plan view”.

In the following description, for example, with respect to a substrate, the description “on a substrate” represents any one of when something is disposed in contact with the substrate, when something is disposed above the substrate with another structure intervening therebetween, and when something is disposed so that a part thereof is in contact with the substrate and another part thereof is located above the substrate with another structure intervening therebetween.

It is assumed that a description “an upper surface of a certain configuration” represents a surface at the positive side in the Z-axis direction of that configuration, for example, an “upper surface of substrate” represents a surface at the positive side in the Z-axis direction of a movable body.

It is assumed that a description “a lower surface of a certain configuration” represents a surface at the negative side of in the Z-axis direction of that configuration, for example, a “lower surface of the substrate” represents a surface at the negative side in the Z-axis direction of the movable body.

It is assumed that a description “an obverse surface and a reverse surface of a certain configuration” represents surfaces appearing outside that configuration, the obverse surface represents a surface at the positive side in the Z-axis direction of that configuration, and the reverse surface represents a surface at the negative side in the Z-axis direction of that configuration.

### 1. Embodiment 1

### 1.1. Schematic Configuration of Resonator Device

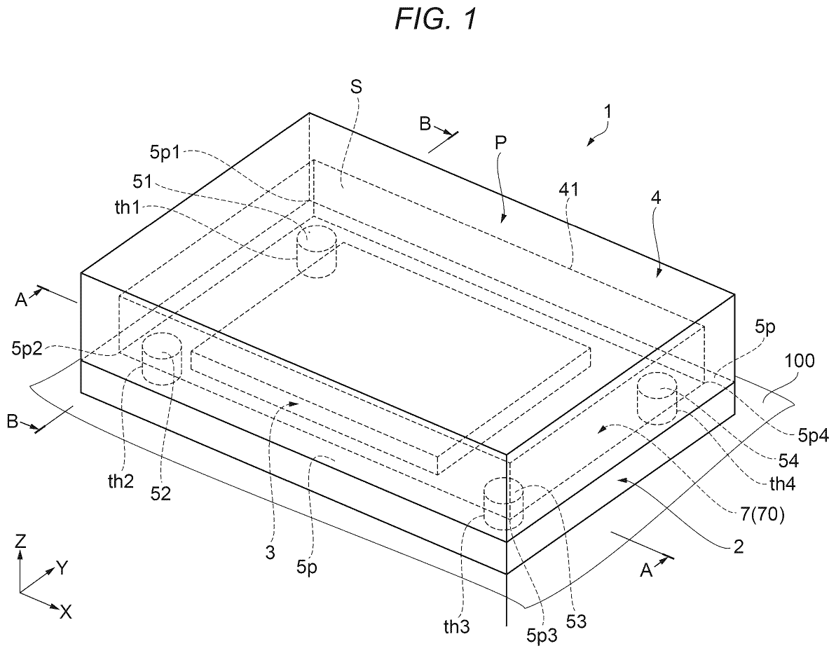

FIGS. 1 to 7 show a schematic configuration of a resonator device 1 according to the present embodiment.

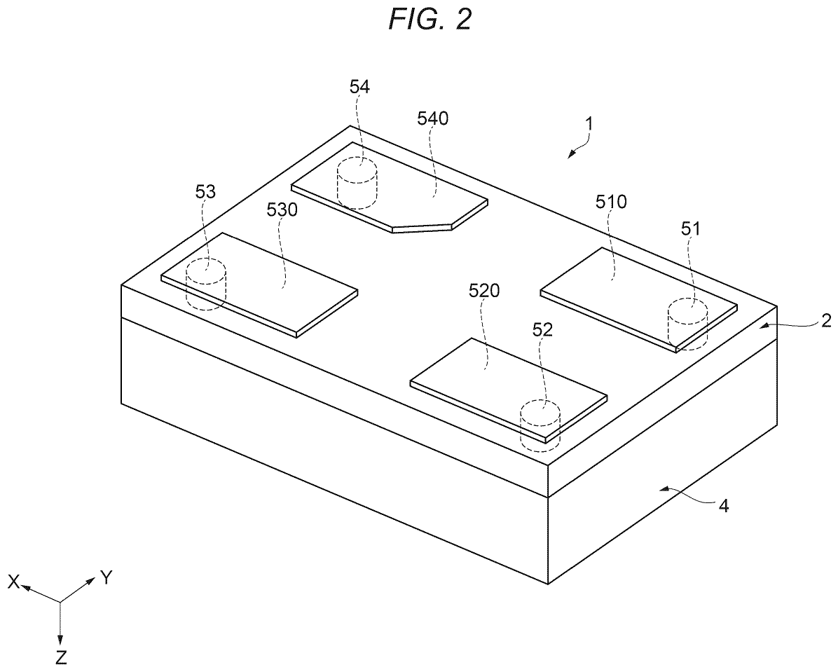

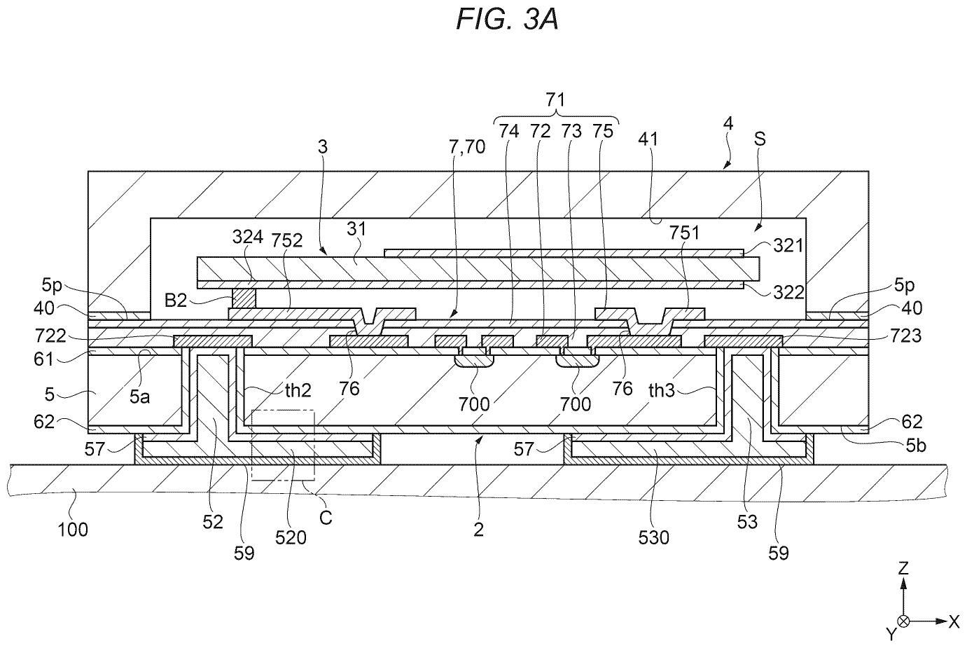

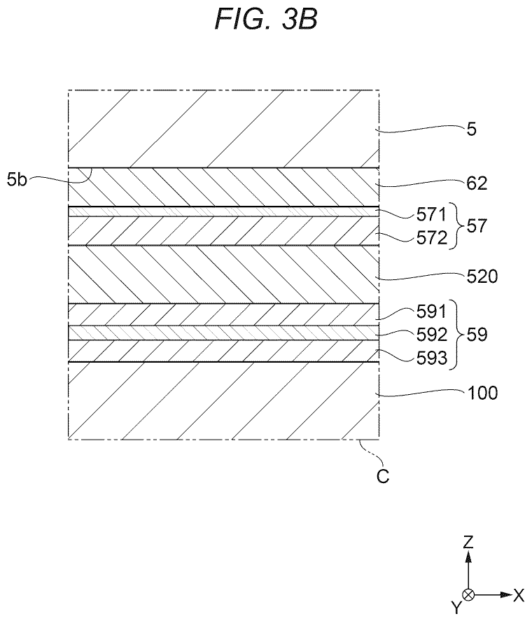

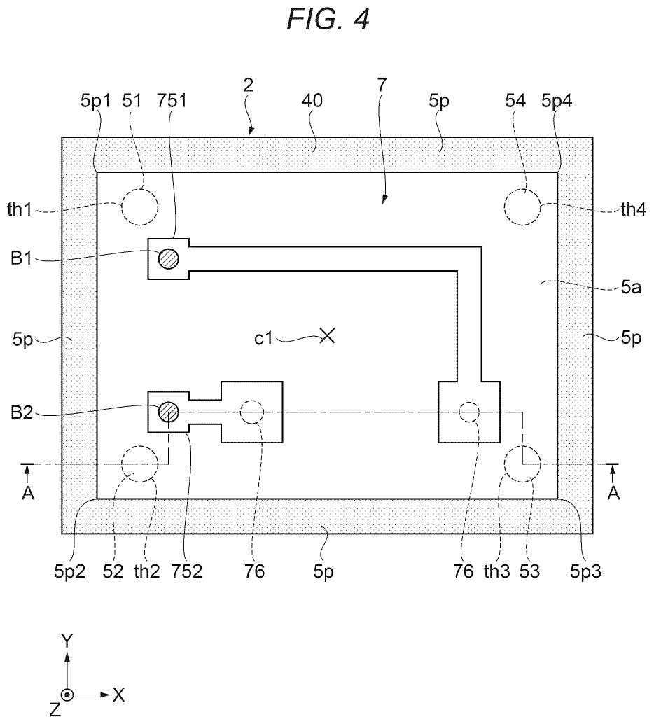

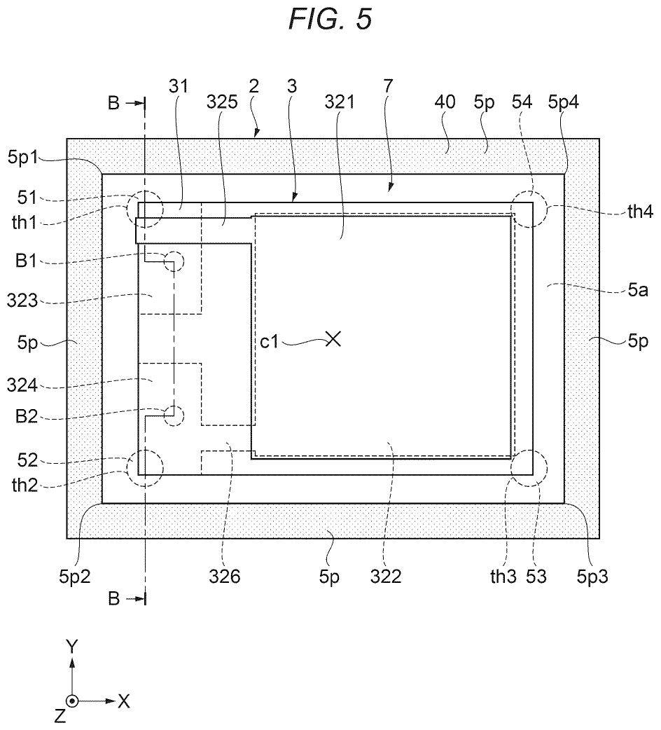

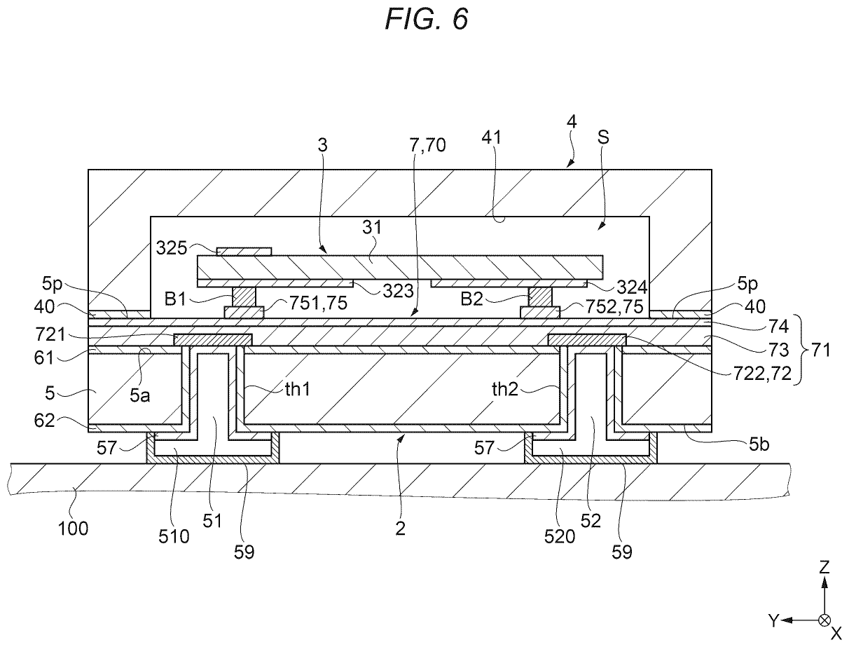

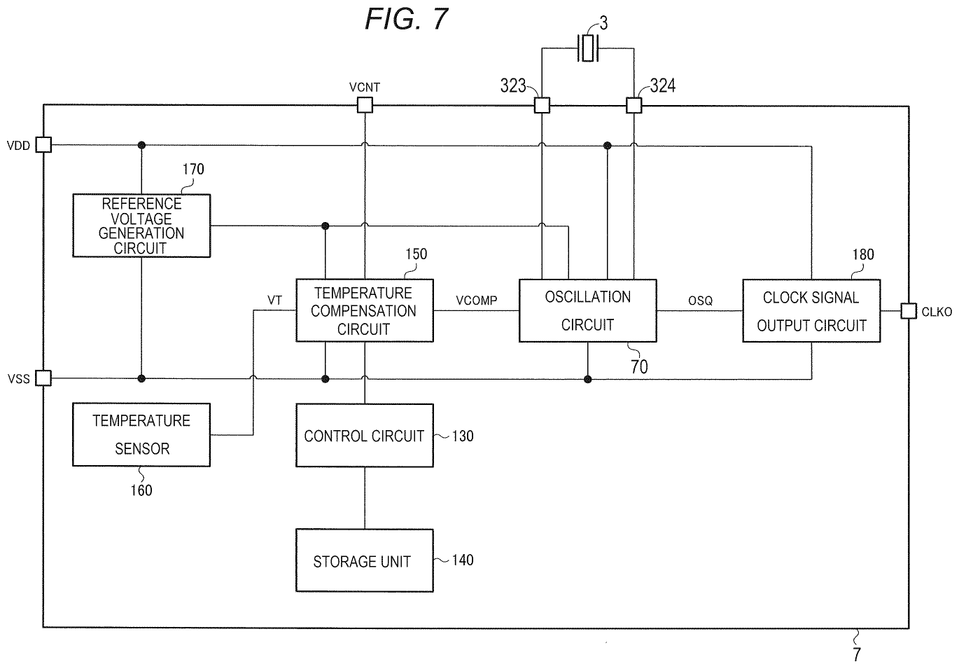

FIG. 1 is a perspective view of the resonator device 1 according to Embodiment 1. FIG. 2 is a perspective view of the resonator device 1 viewed from a reverse side. FIG. 3A is a cross-sectional view of the resonator device 1 along the line A-A in FIGS. 1 and 4. FIG. 3B is an enlarged view of the region C in FIG. 3A. FIG. 4 is a plan view of a semiconductor substrate 5. FIG. 5 is a plan view of the semiconductor substrate 5 and the resonator 3. FIG. 6 is a cross-sectional view of the resonator device 1 along the line B-B in FIGS. 1 and 5. FIG. 7 is a block diagram showing a configuration example of a semiconductor circuit 7.

The resonator device 1 shown in FIG. 1 is an oscillator, and more specifically, is a quartz crystal oscillator obtained by integrating a resonator 3 made of quartz crystal and an oscillation circuit 70 with each other into a single package. For example, the resonator device 1 is mounted on a mounting substrate 100 and outputs a reference signal to the mounting substrate 100. In the present embodiment, the resonator 3 is an example of a resonator element.

The resonator device 1 includes a semiconductor device 2, the resonator 3, and a lid 4.

As shown in FIG. 3A, the semiconductor device 2 includes the semiconductor substrate 5 and the semiconductor circuit 7. The semiconductor circuit 7 is disposed on an upper surface 5a of the semiconductor substrate 5.

The resonator 3 is disposed on an upper surface of the semiconductor circuit 7 disposed on the semiconductor substrate 5. As described above, the present embodiment adopts a face-up method in which the resonator 3 is mounted at a side of a surface of the semiconductor substrate 5 on which the semiconductor circuit 7 is formed.

The lid 4 has a recess 41 and is bonded to an outer circumferential portion 5p of the upper surface of the semiconductor device 2 to form a package P. The resonator 3 is housed in a housing space S in the package P. The housing space S is airtight and in a reduced pressure state, and is preferably in a state more approximate to vacuum. As a result, viscous resistance is reduced, and oscillation characteristics of the resonator 3 are improved. However, an atmosphere in the housing space S is not particularly limited.

As shown in FIG. 2, terminals 510, 520, 530, and 540 are disposed on the reverse surface of the resonator device 1. The terminal 510, 520, 530, and 540 are electrically coupled to the semiconductor circuit 7 including the oscillation circuit 70 shown in FIG. 1 via through electrodes 51, 52, 53, and 54.

In the present embodiment, the terminal 510 is an example of a first terminal, the terminal 520 is an example of a second terminal, the terminal 530 is an example of a third terminal, and the terminal 540 is an example of a fourth terminal. The through electrode 51 is an example of a first through electrode, the through electrode 52 is an example of a second through electrode, the through electrode 53 is an example of a third through electrode, and the through electrode 54 is an example of a fourth through electrode.

FIG. 7 is a block diagram showing a configuration example of the semiconductor circuit 7. The semiconductor circuit 7 includes the oscillation circuit 70, a control circuit 130, a storage unit 140, a temperature compensation circuit 150, a temperature sensor 160, a reference voltage generation circuit 170, and a clock signal output circuit 180.

The oscillation circuit 70 is a circuit that generates an oscillation signal using the resonator 3. Specifically, the oscillation circuit 70 is coupled to the resonator 3 via a terminal 323 and a terminal 324. The oscillation circuit 70 generates an oscillation signal by oscillating the resonator 3. For example, in a temperature compensated crystal oscillator (TCXO) or an oven controlled crystal oscillator (OCXO), a control voltage VCOMP corresponding to a detected temperature is input to the oscillation circuit 70, and the oscillation circuit 70 oscillates the resonator 3 with an oscillation frequency corresponding to the control voltage VCOMP. The control voltage VCOMP is a temperature compensating voltage for compensating the temperature characteristics of the oscillation frequency.

The clock signal output circuit 180 outputs a clock signal to a terminal CLKO based on an output signal OSQ of the oscillation circuit 70. The terminal CLKO corresponds to, for example, the terminal 510 in FIG. 2. The clock signal output circuit 180 buffers the output signal OsQ or a signal obtained by frequency-dividing the output signal OSQ, and then outputs the signal thus buffered as the clock signal.

The control circuit 130 controls each part of the semiconductor circuit 7. Further, the control circuit 130 also performs interface processing with a CPU or the like outside the semiconductor circuit 7, and so on. The control circuit 130 is realized by a logic circuit such as a gate array.

The storage unit 140 stores various types of information necessary for an operation of the semiconductor circuit 7. For example, coefficients of a polynomial for temperature compensation necessary for the temperature compensation circuit 150 to perform temperature compensation processing are stored. The storage unit 140 is, for example, a nonvolatile memory.

The temperature compensation circuit 150 outputs the control voltage VCOMP based on a temperature detection signal VT from the temperature sensor 160 and a control voltage of the oscillation frequency input from the outside via a terminal VCNT. The terminal 520, for example, corresponds to the terminal VCNT in FIG. 2.

The temperature sensor 160 is a sensor that detects the temperature of the semiconductor circuit 7. For example, the temperature sensor 160 can be configured with a diode, or the like. The temperature sensor 160 configured with a diode performs temperature detection using temperature dependency of a forward voltage of the diode, and then outputs the temperature detection signal VT.

The reference voltage generation circuit 170 is a circuit that generates electric power, reference voltages, bias voltages, bias currents, and so on to be supplied to each part of the semiconductor circuit 7. To the reference voltage generation circuit 170, a high-potential side power supply is input via a terminal VDD coupled to a high-potential side power supply, and a low-potential side power supply (the ground) is input via a terminal VSS coupled to a low-potential side power supply. In FIG. 2, the terminal 530, for example, corresponds to the terminal VDD, and the terminal 540, for example, corresponds to the terminal VSS. The reference voltage generation circuit 170 supplies a reference voltage to the temperature compensation circuit 150 or supplies a power supply voltage to the oscillation circuit 70.

### 1.2. Configuration of Semiconductor Device 2

As described above, the semiconductor device 2 includes the semiconductor substrate 5 and the semiconductor circuit 7.

### 1.2.1. Configuration of Semiconductor Substrate 5

The semiconductor substrate 5 is a silicon substrate. As the semiconductor substrate 5, a substrate formed of a semiconductor material other than silicon, such as Ge, GaP, GaAs, or InP may be used. The semiconductor substrate 5 has the upper surface 5a as a first surface and a lower surface 5b as a second surface, wherein the first surface and the second surface have an obverse-reverse relationship with each other.

As illustrated in FIGS. 3A, 4, 5, and 6, the semiconductor substrate 5 includes through holes th1, th2, th3, and th4 penetrating from the upper surface 5a to the lower surface 5b.

The through electrodes 51, 52, 53, and 54 are provided to the through holes th1, th2, th3, and th4, respectively. Each of the through electrodes 51, 52, 53, and 54 is a through silicon via (TSV). Note that the cross sections of the through electrode 54 and the through hole th4 are not illustrated, but are configured similarly to those of the through electrodes 51, 52, and 53 and the through holes th1, th2, and th3.

As shown in FIG. 1, the through electrodes 51, 52, 53, and 54 are respectively arranged near the four corners of the outer circumferential portion 5p of the semiconductor substrate 5. More specifically, as shown in FIGS. 4 and 5, the through electrode 51 is disposed closer to a corner portion 5p1 of the outer circumferential portion 5p than to the center c1 of the upper surface 5a of the semiconductor substrate 5 in the plan view. The through electrode 52 is disposed closer to a corner portion 5p2 of the outer circumferential portion 5p than to the center c1 of the upper surface 5a of the semiconductor substrate 5 in the plan view. The through electrode 53 is disposed closer to a corner portion 5p3 of the outer circumferential portion 5p than to the center c1 of the upper surface 5a of the semiconductor substrate 5 in the plan view. The through electrode 54 is disposed closer to a corner portion 5p4 of the outer circumferential portion 5p than to the center c1 of the upper surface 5a of the semiconductor substrate 5 in the plan view. In the present embodiment, the corner portion 5p1 is an example of a first corner portion, the corner portion 5p2 is an example of a second corner portion, the corner portion 5p3 is an example of a third corner portion, and the corner portion 5p4 is an example of a fourth corner portion.

As described above, in the present embodiment, the semiconductor circuit 7 including the oscillation circuit 70 is disposed on a surface of the semiconductor substrate 5, the surface facing the resonator 3. Therefore, the resonator device 1 needs to be provided with at least four through electrodes 51, 52, 53, and 54 in order to make the semiconductor circuit 7 function. In other words, in the present embodiment, it is necessary to provide at least four through holes th1, th2, th3, and th4 to the semiconductor substrate 5.

However, when the through electrodes 51, 52, 53, and 54 are provided to the semiconductor substrate 5, there is a possibility that the strength of the semiconductor substrate 5 decreases. In the present embodiment, in order to suppress a decrease in the strength of the semiconductor substrate 5, the positions at which the through electrodes 51, 52, 53, and 54 are disposed are made closer to the outer circumferential portion 5p. In other words, in the present embodiment, the positions at which the through holes th1, th2, th3, and th4 are disposed are made closer to the outer circumferential portion 5p. Since the lid 4 is bonded to the outer circumferential portion 5p, the semiconductor substrate 5 can be reinforced by the lid 4.

Furthermore, it is more preferable in terms of strength to dispose the through electrodes 51, 52, 53, and 54 one by one close to the four corners 5p1, 5p2, 5p3, and 5p4 of the outer circumferential portion 5p. This is because, since the lid 4 and the outer circumferential portion 5p each have a rectangular shape, the reinforcing effect by the lid 4 is higher at the positions of the corner portions 5p1, 5p2, 5p3, and 5p4 where two sides of the outer circumferential portion 5p cross each other than in side portions between the corner portions.

As shown in FIG. 3A and FIG. 6, an insulating film 61 is disposed on the upper surface 5a of the semiconductor substrate 5. An insulating film. is disposed on the lower surface 5b of the semiconductor substrate 5. The insulating film 62 is also disposed on the inner circumferential surfaces of the through holes th1, th2, th3, and th4. The insulating films 61, 62 are made of, for example, silicon oxide (SiO₂).

The through electrode 51 and the terminal 510 are copper (Cu) plated electrodes formed by an electrolytic plating method. The through electrode 51 and the terminal 510 are formed in the same step, and are therefore integrally configured. In the present embodiment, portions overlapping the through holes th1, th2, th3, and th4 in the plan view are defined as the through electrodes 51, 52, 53, and 54, respectively.

A seed layer 57 is disposed between the through electrode 51 and the terminal 510, and the insulating film 62. Note that the through electrode 51 and the terminal 510 may be formed by copper paste printing. The through electrode 52 and the terminal 520, the through electrode 53 and the terminal 530, and the through electrode 54 and the terminal 540 are also configured similarly to the through electrode 51 and the terminal 510.

A conductive protective film 59 is disposed so as to cover the through electrode 51 and the terminal 510. The conductive protective film 59 is provided for suppressing outgas generated from the through electrode 51 and the terminal 510. Since the through electrode 51 and the terminal 510 formed of the copper plating electrode contain moisture and hydrogen, there is a possibility that the moisture and the hydrogen are released as the outgas. The outgas causes a defect such as a contact failure on an electrical bonding surface to the mounting substrate 100. The through electrode 52 and the terminal 520, the through electrode 53 and the terminal 530, and the through electrode 54 and the terminal 540 are also covered with the conductive protective film 59 similarly to the through electrode 51 and the terminal 510.

FIG. 3B is an enlarged cross-sectional view of the region C in FIG. 3A, and illustrates a configuration of the seed layer 57 and the conductive protective film 59.

The seed layer 57 has a two-layer laminated structure including a titanium-tungsten alloy (TiW) sputtered film 571 and a copper sputtered film 572. Instead of the titanium-tungsten alloy of the seed layer 57, chromium (Cr) or titanium (Ti) may be used.

The conductive protective film 59 has a three-layer laminated structure including a nickel (Ni) electroless plating film 591, a palladium (Pd) electroless plating film 592, and a gold (Au) electroless plating film 593.

### 1.2.2. Configuration of Semiconductor Circuit 7

As shown in FIG. 3A, the semiconductor circuit 7 includes a plurality of elements 700 formed on the upper surface 5a of the semiconductor substrate 5, and a stacked body 71 stacked on the upper surface 5a of the semiconductor substrate 5.

The stacked body 71 includes an interconnection layer 72 formed on the upper surface 5a of the semiconductor substrate 5, an insulating layer 73 formed on an upper surface of the interconnection layer 72, a passivation film 74 formed on an upper surface of the insulating layer 73, and a terminal layer 75 formed on an upper surface of the passivation film 74. The interconnection layer 72 is not limited to a single layer. A plurality of interconnection layers 72 may be provided via a plurality of insulating layers 73.

The plurality of elements 700, the interconnection layer 72, and the terminal layer 75 are electrically coupled to each other via contact holes 76, coupling members (not illustrated), and so on to form the oscillation circuit 70. The elements 700 are, for example, transistors, resistors, capacitive elements, and so on.

In this way, by providing the semiconductor circuit 7 to the semiconductor substrate 5, it is possible to effectively use a space in the semiconductor substrate 5. Further, since the semiconductor circuit 7 can be integrally formed with the resonator device 1, it is possible to achieve a reduction in size of a whole of the device.

As illustrated in FIGS. 3A and 6, the interconnection layer 72 includes electrode pads 721, 722, and 723. The electrode pad 721 overlaps the through hole th1 and the through electrode 51 and is electrically coupled to the through electrode 51. The electrode pad 722 overlaps the through hole th2 and the through electrode 52 and is electrically coupled to the through electrode 52. The electrode pad 723 overlaps the through hole th3 and the through electrode 53 and is electrically coupled to the through electrode 53. Although not illustrated, the interconnection layer 72 includes an electrode pad 724 that overlaps the through hole th4 and the through electrode 54 and is electrically coupled to the through electrode 54.

The terminal layer 75 includes an internal terminal 751 and an internal terminal 752 that also serve as interconnections. The internal terminal 751 electrically couples the interconnection layer 72 and a bonding member B1. The internal terminal 752 electrically couples the interconnection layer 72 and a bonding member B2.

### 1. 3. Configuration of Lid 4

The lid 4 is a silicon substrate similarly to the semiconductor substrate 5. As a result, linear expansion coefficients of the semiconductor substrate 5 and the lid 4 become equal, generation of thermal stress caused by thermal expansion is prevented, and the resonator device 1 having excellent vibration characteristics is obtained. Further, since the resonator device 1 can be formed by a semiconductor process, the resonator device 1 can be manufactured with high accuracy, and the reduction in size of the resonator device 1 can be achieved. However, the lid 4 is not particularly limited, and a substrate made of a semiconductor material other than silicon such as Ge, GaP, GaAs, or InP may be used.

### 1.4. Configuration of resonator 3

As shown in FIGS. 3A, 5, and 6, the resonator 3 has a vibrating substrate 31 and excitation electrodes 321, 322.

The vibrating substrate 31 has a thickness-shear vibration mode, and is formed of an AT-cut quartz crystal substrate in the present embodiment. Since the AT-cut quartz crystal substrate has cubic frequency-temperature characteristics, the resonator 3 having excellent temperature characteristics is obtained.

The excitation electrode 321 is disposed on the upper surface of the vibrating substrate 31 and is electrically coupled to the terminal 323 via an interconnection 325.

The excitation electrode 322 is disposed on the lower surface of the vibrating substrate 31 and is electrically coupled to the terminal 324 via an interconnection 326.

Note that the configuration of the resonator 3 is not limited to the configuration described above. For example, the resonator 3 may have a mesa shape in which a vibration region sandwiched between the excitation electrodes 321, 322 protrudes from the periphery thereof, or conversely, the vibration region may have an inverted mesa shape in which the vibration region is recessed from the periphery thereof. Further, bevel machining in which the periphery of the vibrating substrate 31 is ground, or convex machining in which the upper surface and the lower surface are made into convex surfaces may be performed. Further, the resonator 3 is not limited to one that vibrates in the thickness-shear vibration mode, and may be, for example, a resonator in which a plurality of vibrating arms make a flexural vibration in an in-plane direction. That is, the vibrating substrate 31 is not limited to one formed from the AT-cut quartz crystal substrate, and may be formed of a quartz crystal substrate other than the AT-cut quartz crystal substrate such as an X-cut quartz crystal substrate, a Y-cut quartz crystal substrate, a Z-cut quartz crystal substrate, a BT-cut quartz crystal substrate, an SC-cut quartz crystal substrate, or an ST-cut quartz crystal substrate. Further, although the vibrating substrate 31 is made of quartz crystal in the present embodiment, this is not a limitation, and the vibrating substrate 31 may be formed of a piezoelectric single crystal body made of lithium niobate, lithium tantalate, lithium tetraborate, langasite crystal, potassium niobate, or gallium phosphate, or may be formed of a piezoelectric single crystal body made of other materials than those described above. Furthermore, the resonator 3 is not limited to a resonator of a piezoelectric drive type, and may be a resonator of an electrostatic drive type using electrostatic force.

As shown in FIGS. 3A and 6, the resonator 3 is bonded to the internal terminals 751, 752 with the bonding members B1, B2 having electrical conductivity. Accordingly, the resonator 3 3 and the semiconductor circuit 7 are electrically coupled via the bonding members B1, B2. In the present embodiment, the bonding members B1, B2 are bumps formed by electroless plating.

### 1.5. Method of Manufacturing Resonator Device

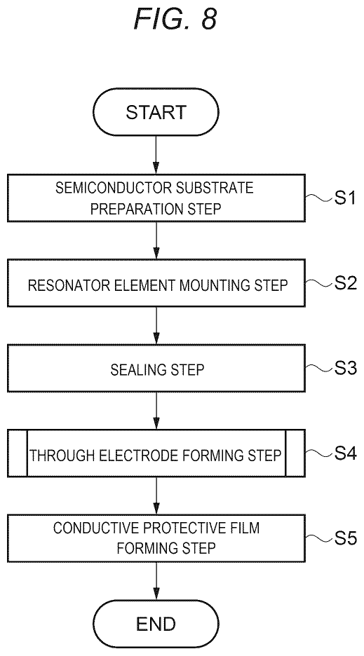

FIGS. 8 to 21 are diagrams illustrating a method of manufacturing the resonator device 1 according to the present embodiment.

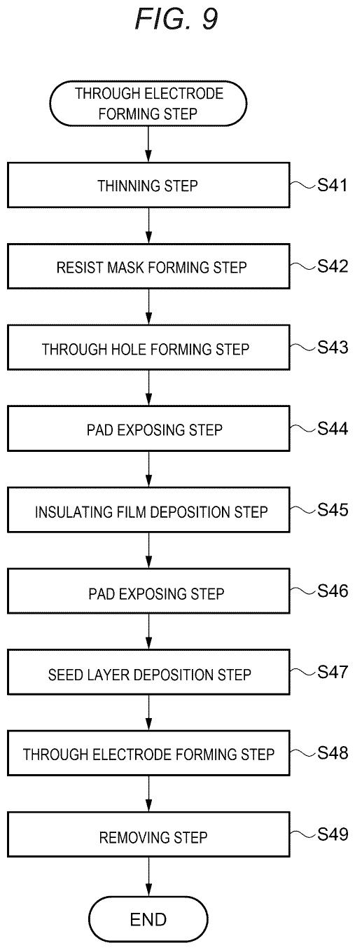

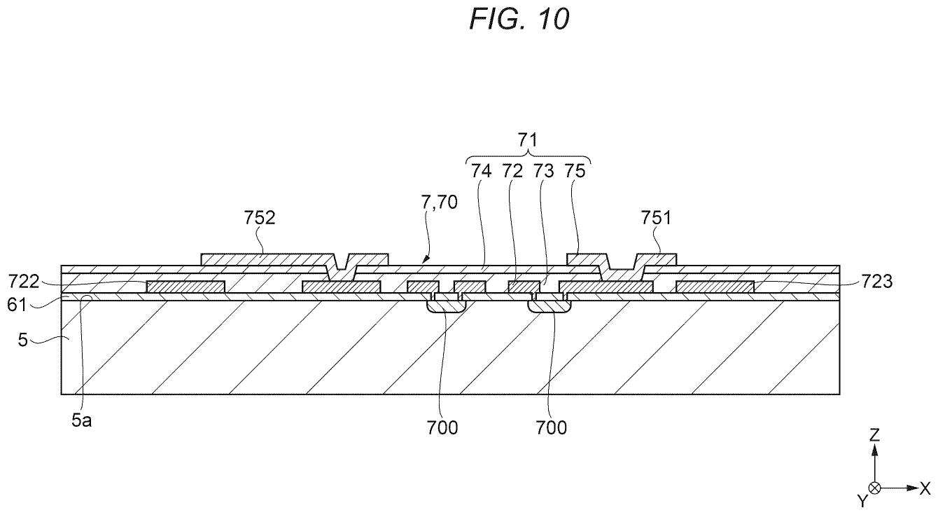

FIG. 8 is a flowchart illustrating manufacturing steps of the resonator device 1. FIG. 9 is a flowchart showing details of a through electrode forming step S4 in FIG. 8. FIGS. 10 to 21 are cross-sectional views showing an aspect of the manufacturing process, and each cross-sectional view shows a cross section at a position corresponding to the line A-A in FIGS. 1 and 4.

As shown in FIG. 8, the method of manufacturing the resonator device 1 includes a semiconductor substrate preparation step S1, a resonator element mounting step S2, a sealing step S3, the through electrode forming step S4, and a conductive protective film forming step S5.

In the semiconductor substrate preparation step S1, as shown in FIG. 10, the semiconductor substrate 5 is prepared, and the semiconductor circuit 7 is formed at the upper surface 5a side. Thus, a base material of the semiconductor device 2 is obtained.

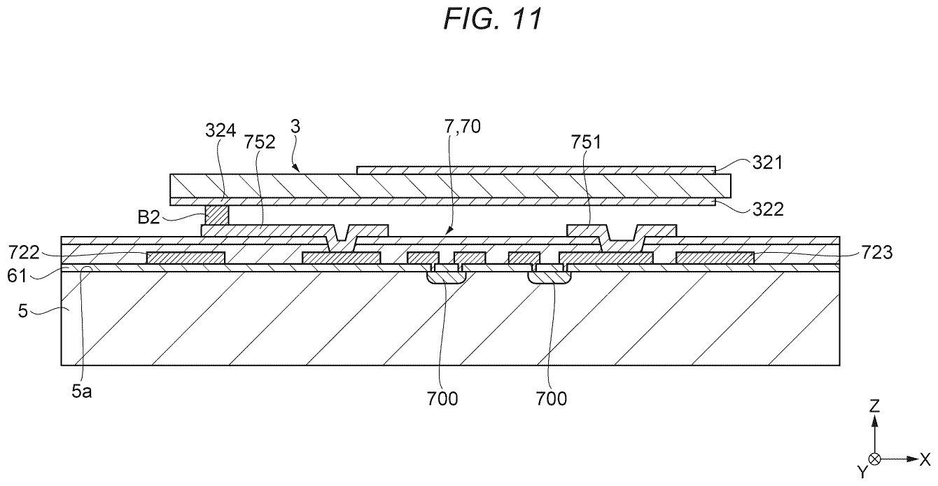

In the resonator element mounting step S2, as shown in FIG. 11, the resonator 3 is bonded to the internal terminals 751, 752 via the bonding members B1, B2.

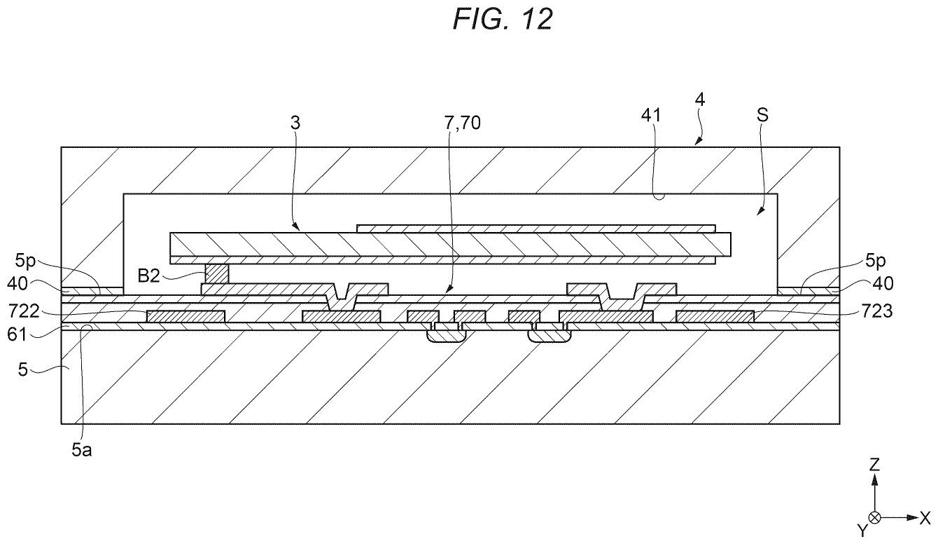

In the sealing step S3, as shown in FIG. 12, the lid 4 is bonded to the outer circumferential portion 5p of the upper surface 5a of the semiconductor substrate 5 via a bonding member 40 in a reduced-pressure state to vacuum-seal the resonator 3 in the housing space S.

As shown in FIG. 9, the through electrode forming step S4 includes a thinning step S41, a resist mask forming step S42, a through hole forming step S43, a pad exposing step S44, an insulating film deposition step S45, a pad exposing step S46, a seed layer deposition step S47, a through electrode forming step S48, and a removing step S49.

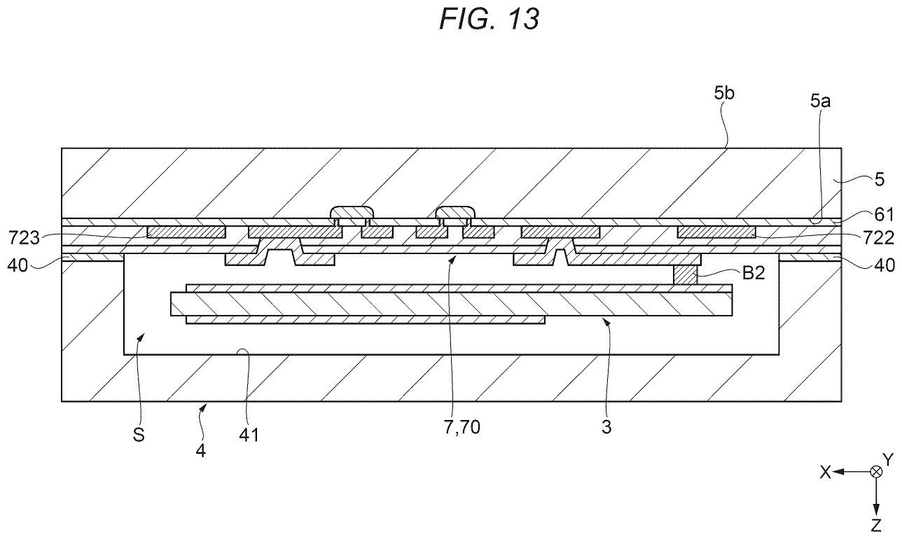

In the thinning step S41, as shown in FIG. 13, the semiconductor substrate 5 is ground and polished from the lower surface 5b side to thin the semiconductor substrate 5 to a predetermined thickness.

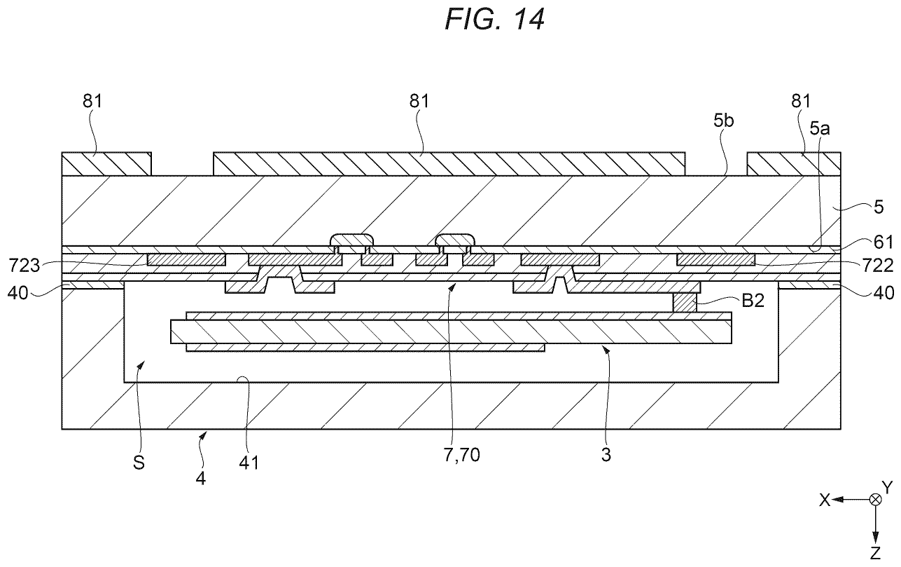

In the resist mask forming step S42, as shown in FIG. 14, a resist is applied to the lower surface 5b of the semiconductor substrate 5, and then the resist is patterned to form a resist mask 81 having openings at positions corresponding to the through holes th1, th2, th3, and th4.

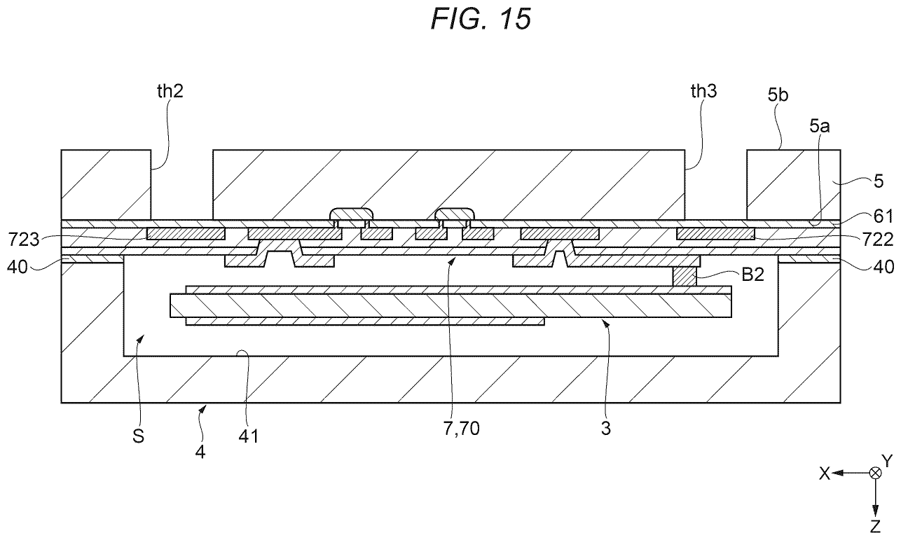

In the through hole forming step S43, as shown in FIG. 15, the semiconductor substrate 5 is dry-etched to provide the semiconductor substrate 5 with the through holes th1, th2, th3, and th4 which reach the insulating film 61 at positions corresponding to the electrode pads 721, 722, 723, and 724. Subsequently, in this step, the resist mask 81 is removed.

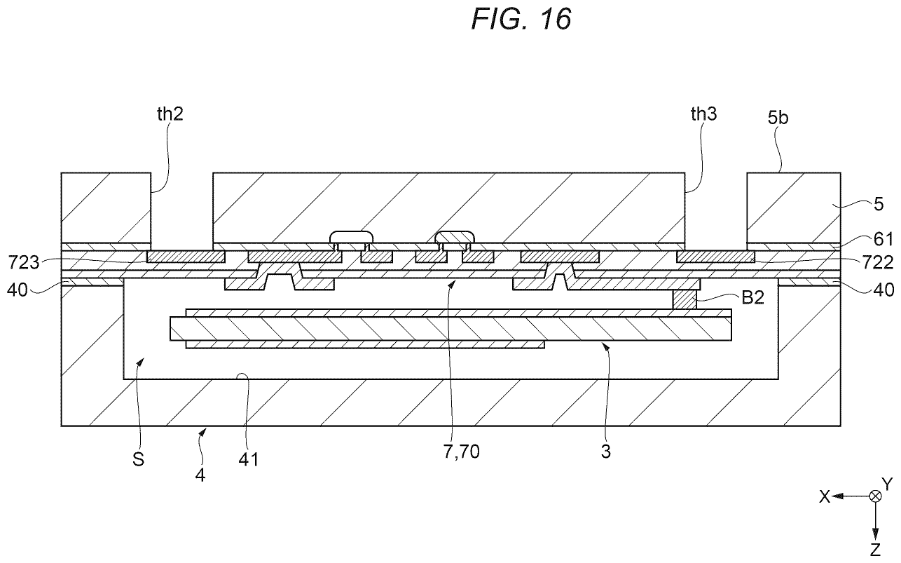

In the pad exposing step S44, as shown in FIG. 16, the insulating film 61 at the bottoms of the through holes th1, th2, th3, and th4 is removed to expose the electrode pads 721, 722, 723, and 724 at the bottoms of the through holes th1, th2, th3, and th4.

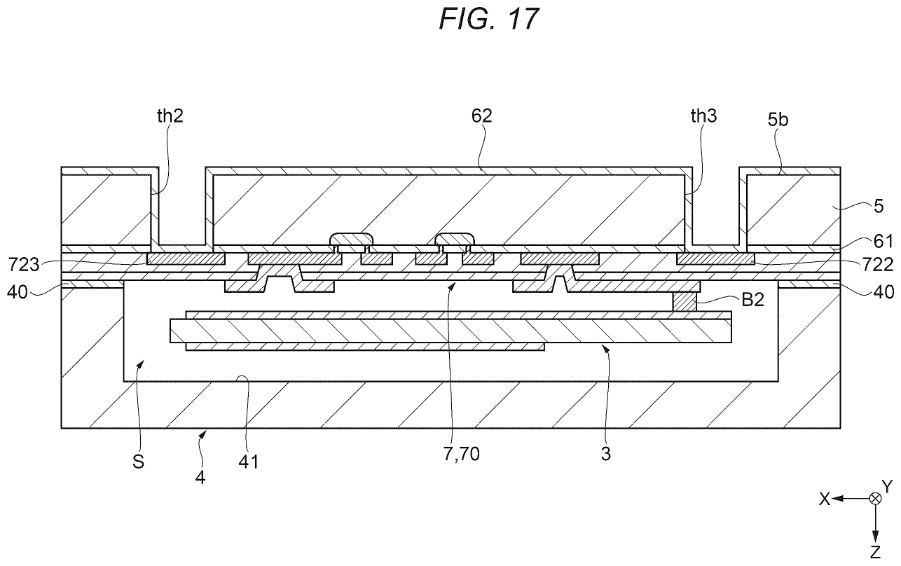

In the insulating film deposition step S45, as shown in FIG. 17, the insulating film 62 is formed on the lower surface 5b of the semiconductor substrate 5 and the inner surfaces of the through holes th1, th2, th3, and th4.

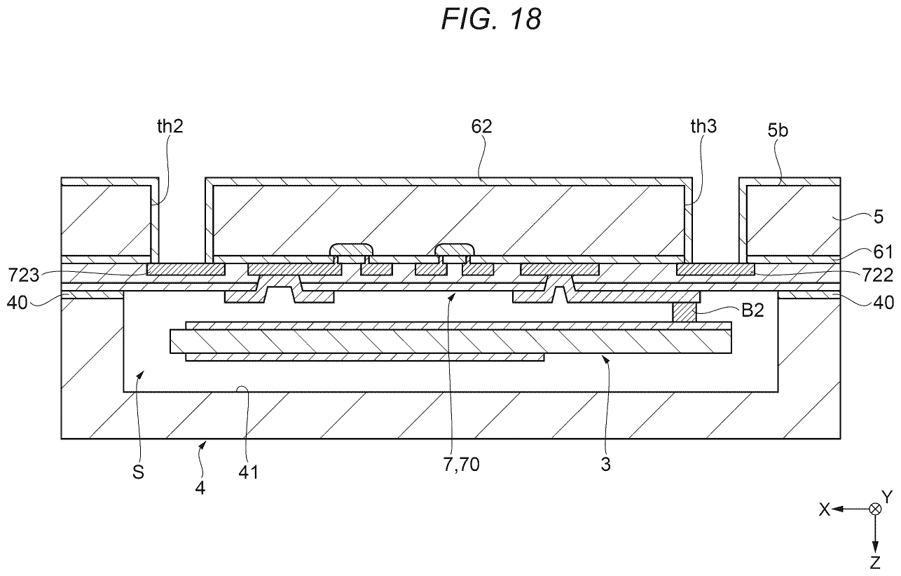

In the pad exposing step S46, as shown in FIG. 18, the insulating film 62 at the bottoms of the through holes th1, th2, th3, and th4 is removed to expose the electrode pads 721, 722, 723, and 724 at the bottoms of the through holes th1, th2, th3, and th4. Note that when the insulating film 62 on the inner circumferential surfaces of the through holes th1, th2, th3, and th4 is removed together when removing the insulating film 62 at the bottoms of the through holes th1, th2, th3, and th4, an organic insulating film may be provided on the inner circumferential surfaces of the through holes th1, th2, th3, and th4.

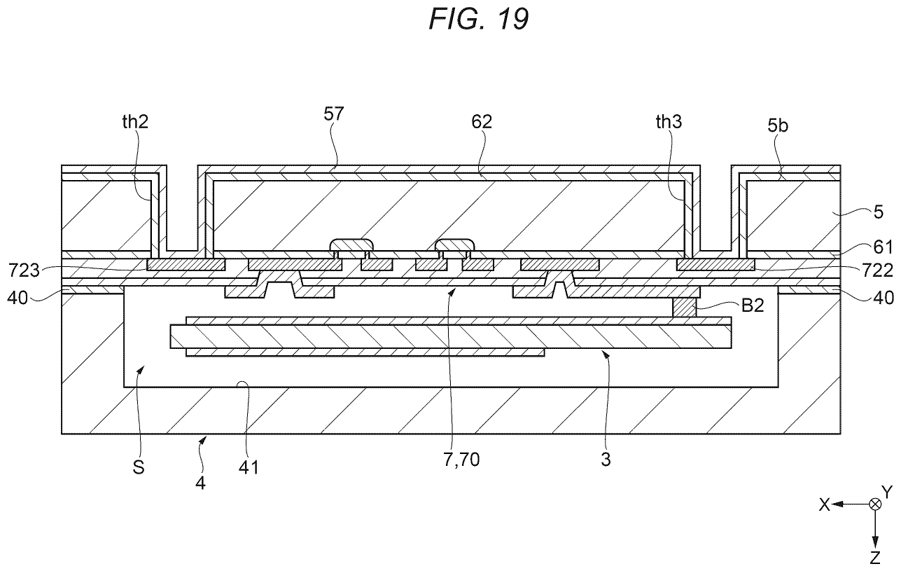

In the seed layer deposition step S47, as shown in FIG. 19, the seed layer 57 is formed by sputtering so as to cover the lower surface 5b of the semiconductor substrate 5 and the insulating film 62 on the inner surfaces of the through holes th1, th2, th3, and th4. As illustrated in FIG. 3B, the seed layer 57 is a laminated film including a titanium-tungsten alloy sputtered film 571 as a deep layer and the copper sputtered film 572 as a surface layer. Instead of the titanium-tungsten alloy of the seed layer 57, chromium or titanium may be used.

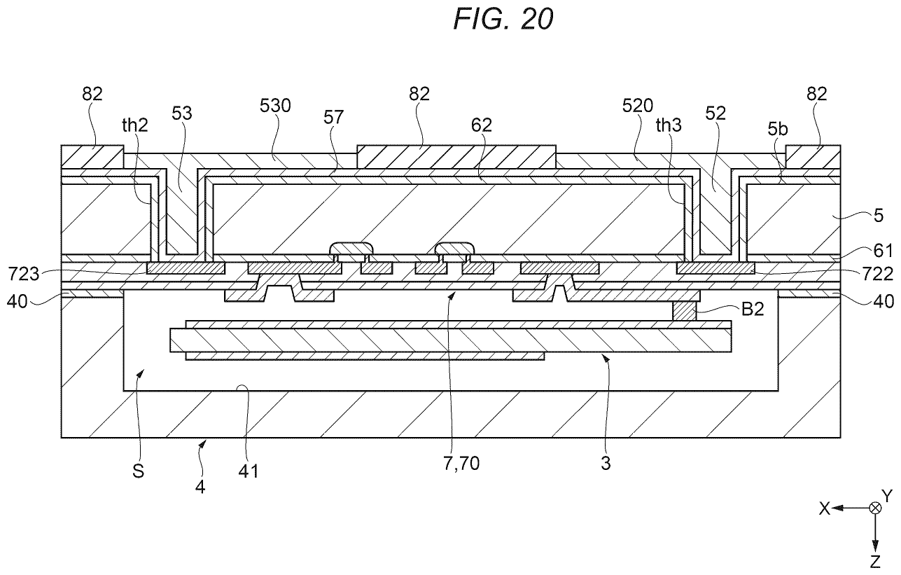

In the through electrode forming step S48, as shown in FIG. 20, a resist mask 82 having openings at positions corresponding to the through holes th1, th2, th3, and th4 and the terminals 510, 520, 530, and 540 is formed. Subsequently, in this step, copper plating is deposited in the openings by electrolytic plating to form the through electrodes 51, 52, 53, and 54 and the terminals 510, 520, 530, and 540.

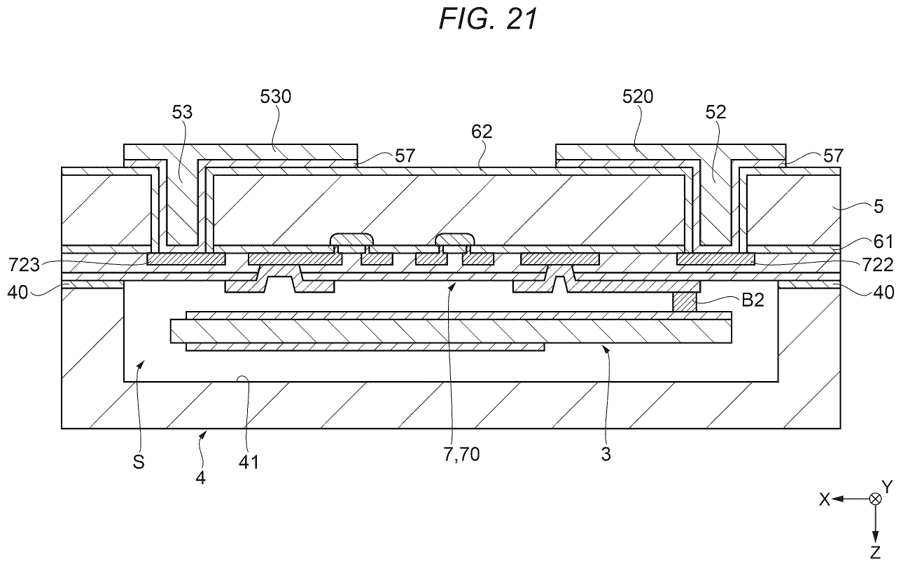

In the removing step S49, as shown in FIG. 21, after the resist mask 82 is removed, the seed layer 57 exposed from the through electrodes 51, 52, 53, and 54 and the terminals 510, 520, 530, and 540 is removed by etching using the copper plating as a mask.

In the conductive protective film forming step S5, as shown in FIGS. 3A and 6, the conductive protective film 59 which covers the through electrodes 51, 52, 53, and 54 and the terminals 510, 520, 530, and 540 is formed by electroless plating. The conductive protective film 59 is a laminated film including the nickel electroless plating film 591 as a deep layer, the palladium electroless plating film 592 as an intermediate layer, and the gold electroless plating film 593 as a surface layer.

As described above, the resonator device 1 according to the present embodiment includes the semiconductor substrate 5 which has the upper surface 5a as the first surface and the lower surface 5b as the second surface in the obverse-reverse relationship and has the through hole th1 penetrating from the upper surface 5a to the lower surface 5b, the resonator 3 as the resonator element disposed on the semiconductor substrate 5, the lid 4 which is bonded to the outer circumferential portion 5p of the upper surface 5a of the semiconductor substrate 5 to house the resonator 3 between the lid 4 and the upper surface 5a of the semiconductor substrate 5, the oscillation circuit 70 disposed on the upper surface 5a of the semiconductor substrate 5 and oscillating the resonator 3, the terminal 510 disposed on the lower surface 5b of the semiconductor substrate 5, and the through electrode 51 provided to the through hole th1 of the semiconductor substrate 5 to electrically couple the terminal 510 and the oscillation circuit 70 to each other, wherein the through electrode 51 is disposed closer to the outer circumferential portion 5p than to the center c1 of the upper surface 5a in the plan view of the semiconductor substrate 5.

As described above, in the present embodiment, the through electrode 51 provided to the semiconductor substrate 5 is disposed closer to the outer circumferential portion 5p than to the center c1 of the upper surface 5a. Further, since the lid 4 is bonded to the outer circumferential portion 5p, the strength of the outer circumferential portion 5p is higher than that of the center c1 in the resonator device 1. Therefore, in the resonator device 1 according to the present embodiment, even when the through electrode 51 is provided to the semiconductor substrate 5, it is possible to suppress a decrease in the strength of the semiconductor substrate 5.

In the resonator device 1 according to the present embodiment, the outer circumferential portion 5p of the upper surface 5a as the first surface has the corner portion 5p1, and the through electrode 51 is disposed near the corner portion 5p1.

As described above, in the present embodiment, the through electrode 51 is disposed near the corner portion 5p1. Since the lid 4 and the outer circumferential portion 5p each have a rectangular shape, the strength is higher at the position of the corner portion 5p1 where the two sides of the outer circumferential portion 5p cross each other than in the side portion of the outer circumferential portion 5p. Therefore, in the resonator device 1 according to the present embodiment, even when the through electrode 51 is provided to the semiconductor substrate 5, it is possible to suppress a decrease in the strength of the semiconductor substrate 5.

In the resonator device 1 according to the present embodiment, the terminal 510 and the through electrode 51 are covered with the conductive protective film 59.

As described above, in the present embodiment, the terminal 510 and the through electrode 51 are covered with the conductive protective film 59. Therefore, when the resonator device 1 is mounted on the mounting substrate 100, it is possible to suppress the occurrence of a defect such as a contact failure on the electrical bonding surface to the mounting substrate 100.

In the resonator device 1 according to the present embodiment, the conductive protective film 59 is formed of a laminated film of nickel, palladium, and gold.

As described above, in the present embodiment, the terminal 510 and the through electrode 51 are covered with the conductive protective film 59 made of the laminated film of nickel, palladium, and gold. Therefore, when the resonator device 1 is mounted on the mounting substrate 100, it is possible to suppress the occurrence of a defect such as a contact failure on the electrical bonding surface to the mounting substrate 100.

The resonator device 1 according to the present embodiment includes the insulating film 62 disposed between the through hole th1 and the through electrode 51, and the seed layer 57 disposed between the insulating film 62 and the through electrode 51, and the through electrode 51 is made of copper.

As described above, in the present embodiment, the insulating film 62, the seed layer 57, and the through electrode 51 are provided on the inner circumferential surface of the through hole th1, and the through electrode 51 is made of copper. Therefore, the through electrode 51 excellent in electrical connectivity and conductivity can be formed.

The resonator device 1 of the present embodiment includes the semiconductor substrate 5 having the upper surface 5a as the first surface and the lower surface 5b as the second surface in the obverse-reverse relationship, and having the through hole th1 as the first through hole, the through hole th2 as the second through hole, the through hole th3 as the third through hole, and the through hole th4 as the fourth through hole all penetrating from the upper surface 5a to the lower surface 5b, the resonator 3 as the resonator element disposed on the semiconductor substrate 5, the lid 4 which is bonded to the outer circumferential portion 5p of the upper surface 5a of the semiconductor substrate 5 to house the resonator 3 between the lid 4 and the upper surface 5a of the semiconductor substrate 5, the oscillation circuit 70 that is disposed on the upper surface 5a of the semiconductor substrate 5 and oscillates the resonator 3, the terminal 510 as the first terminal, the terminal 520 as the second terminal, the terminal 530 as the third terminal, and the terminal 540 as the fourth terminal all arranged on the lower surface 5b of the semiconductor substrate 5, the through electrode 51 as the first through electrode provided to the through hole th1 of the semiconductor substrate 5 to electrically couple the terminal 510 and the oscillation circuit 70, to each other, the through electrode 52 as the second through electrode provided to the through hole th2 of the semiconductor substrate 5 to electrically couple the terminal 520 and the oscillation circuit 70 to each other, the through electrode 53 as the third through electrode provided to the through hole th3 of the semiconductor substrate 5 to electrically couple the terminal 530 and the oscillation circuit 70 to each other, and the through electrode 54 as the fourth through electrode provided to the through hole th4 of the semiconductor substrate 5 to electrically couple the terminal 540 and the oscillation circuit 70 to each other, wherein the through electrode 51, the through electrode 52, the through electrode 53, and the through electrode 54 are disposed closer to the outer circumferential portion 5p than to the center c1 of the upper surface 5a in the plan view of the semiconductor substrate 5.

As described above, in the present embodiment, each of the through electrodes 51, 52, 53, and 54 provided to the semiconductor substrate 5 is disposed closer to the outer circumferential portion 5p than to the center c1 of the upper surface 5a. Further, since the lid 4 is bonded to the outer circumferential portion 5p, the strength of the outer circumferential portion 5p is higher than that of the center c1 in the resonator device 1. Therefore, in the resonator device 1 according to the present embodiment, even when the through electrodes 51, 52, 53, and 54 are provided to the semiconductor substrate 5, it is possible to suppress a decrease in the strength of the semiconductor substrate 5.

In the resonator device 1 according to the present embodiment, the outer circumferential portion 5p of the upper surface 5a includes the corner portion 5p1 as the first corner portion, the corner portion 5p2 as the second corner portion, the corner portion 5p3 as the third corner portion, and the corner portion 5p4 as the fourth corner portion, the through electrode 51 is disposed near the corner portion 5p1, the through electrode 52 is disposed near the corner portion 5p2, the through electrode 53 is disposed near the corner portion 5p3, and the through electrode 54 is disposed near the corner portion 5p4.

As described above, in the present embodiment, the through electrodes 51, 52, 53, and 54 are disposed near the corner portions 5p1, 5p2, 5p3, and 5p4, respectively. Since the lid 4 and the outer circumferential portion 5p each have a rectangular shape, the strength is higher at the positions of the corner portions 5p1, 5p2, 5p3, and 5p4 where two sides of the outer circumferential portion 5p cross each other than in the portion of the side between the respective corner portions of the outer circumferential portion 5p. Therefore, in the resonator device 1 according to the present embodiment, even when the through electrodes 51, 52, 53, and 54 are provided to the semiconductor substrate 5, it is possible to suppress a decrease in the strength of the semiconductor substrate 5.

Although the preferred embodiment is described hereinabove, the present disclosure is not limited to the embodiment described above. The configuration of each part of the present disclosure can be replaced with any configuration that exhibits substantially the same function as that of the embodiment described above.

What is claimed is:

1. A resonator device comprising:
a semiconductor substrate which has a first surface and a second surface in an obverse-reverse relationship and has a through hole penetrating from the first surface to the second surface;
a resonator element provided to the semiconductor substrate;
a lid which is bonded to an outer circumferential portion of the first surface of the semiconductor substrate and is configured to house the resonator element between the lid and the first surface of the semiconductor substrate;
an oscillation circuit which is disposed on the first surface of the semiconductor substrate and is configured to oscillate the resonator element;
a terminal disposed on the second surface of the semiconductor substrate; and
a through electrode which is provided to the through hole of the semiconductor substrate and is configured to electrically couple the terminal and the oscillation circuit, wherein
the through electrode is disposed closer to the outer circumferential portion than to a center of the first surface in a plan view of the semiconductor substrate.

2. The resonator device according to claim 1, wherein
the outer circumferential portion of the first surface has a corner portion, and
the through electrode is disposed near the corner portion.

3. The resonator device according to claim 1, wherein
the terminal and the through electrode are covered with a conductive protective film.

4. The resonator device according to claim 3, wherein the conductive protective film is formed of a laminated film of nickel, palladium, and gold.

5. The resonator device according to claim 3, further comprising:
an insulating film disposed between the through hole and the through electrode; and
a seed layer disposed between the insulating film and the through electrode, wherein
the through electrode is made of copper.

6. A resonator device comprising:
a semiconductor substrate which has a first surface and a second surface in an obverse-reverse relationship and has a first through hole, a second through hole, a third through hole, and a fourth through hole all penetrating from the first surface to the second surface;
a resonator element provided to the semiconductor substrate;
a lid which is bonded to an outer circumferential portion of the first surface of the semiconductor substrate, and is configured to house the resonator element between the lid and the first surface of the semiconductor substrate;
an oscillation circuit which is disposed on the first surface of the semiconductor substrate and is configured to oscillate the resonator element;
a first terminal, a second terminal, a third terminal, and a fourth terminal arranged on the second surface of the semiconductor substrate;
a first through electrode which is provided to the first through hole of the semiconductor substrate and is configured to electrically couple the first terminal and the oscillation circuit;
a second through electrode which is provided to the second through hole of the semiconductor substrate and is configured to electrically couple the second terminal and the oscillation circuit;
a third through electrode which is provided to the third through hole of the semiconductor substrate and is configured to electrically couple the third terminal and the oscillation circuit; and
a fourth through electrode which is provided to the fourth through hole of the semiconductor substrate and is configured to electrically couple the fourth terminal and the oscillation circuit, wherein
the first through electrode, the second through electrode, the third through electrode, and the fourth through electrode are disposed closer to the outer circumferential portion than to a center of the first surface in a plan view of the semiconductor substrate.

7. The resonator device according to claim 6, wherein
the outer circumferential portion of the first surface includes a first corner portion, a second corner portion, a third corner portion, and a fourth corner portion, and
the first through electrode is disposed near the first corner portion, the second through electrode is disposed near the second corner portion, the third through electrode is disposed near the third corner portion, and the fourth through electrode is disposed near the fourth corner portion.
